(19) United States
(12) Patent Application Publication
(10) Pub. No.: US 2025/0299910 A1
(43) Pub. Date: Sep. 25, 2025

(54) CHARGED PARTICLE PROCESSING SYSTEM

(71) Applicant: Multibeam Corporation, Santa Clara, CA (US)

(72) Inventors: Eli Vronsky, San Francisco, CA (US); Randy Hall, Penn Valley, CA (US); Justin Fortner, San Jose, CA (US); Igor Fidelman, Danville, CA (US); Ted Prescop, San Jose, CA (US)

(73) Assignee: Multibeam Corporation, Santa Clara, CA (US)

(21) Appl. No.: 18/808,986

(22) Filed: Aug. 19, 2024

Related U.S. Application Data
(60) Provisional application No. 63/569,402, filed on Mar. 25, 2024.

(51) Int. Cl. H01J 37/20; H01J 37/16; H01J 37/22

(52) U.S. Cl. CPC H01J 37/20; H01J 37/16; H01J 37/22; H01J 2237/002; H01J 2237/166; H01J 2237/2007; H01J 2237/202

(57) ABSTRACT

A processing tool for charged particle processing is described herein. The processing tool has a vacuum chamber, a first support member disposed in an interior of the vacuum chamber, the first support member having a plurality of openings to accept a modular charged particle device through each opening, a second support member disposed in the interior of the vacuum chamber in juxtaposition with the first support member, first and second electrical couplings adjacent to the first and second support members, respectively for connecting to the charged particle devices upon inserting through the respective opening for delivering power and control signals to the modular charged particle devices. Processing systems and methods using such processing tools are also described herein.

### CROSS-REFERENCE TO RELATED APPLICATIONS

This patent application claims benefit of U.S. Provisional Patent Application Ser. No. 63/569,402, filed Mar. 25, 2024, which is entirely incorporated herein by reference.

### FIELD

Embodiments relate to a system for treating substrates using charged particles. In particular, this application is about a system for modular miniature charged particle beam devices that produce charged particles for treatment of a substrate, and associated methods.

### BACKGROUND

Electron beam technologies are used in many manufacturing settings, most notably in semiconductor manufacturing. While electron beam techniques for lithography can enable highly customized variations on a semiconductor wafer, processing an entire workpiece using electron beam lithography can be prohibitively time consuming. Methods and apparatus are needed for faster, more cost-effective electron beam processing.

### SUMMARY

Embodiments described herein provide a processing tool, comprising a vacuum chamber; a first support member disposed in an interior of the vacuum chamber, the first support member having a plurality of openings to accept a modular charged particle device through each opening; a first electrical coupling adjacent to the first support member, the first electrical coupling having a plurality of connections in registration with each of the plurality of openings to connect with electrical conductors on the respective modular charged particle device upon insertion through the opening; a second support member disposed in the interior of the vacuum chamber in juxtaposition with the first support member; and a second electrical coupling adjacent to the second support member, the second electrical coupling having control circuitry with an electrical connection in registration with each of the plurality of openings to connect with a control contact of the respective modular charged particle device upon insertion through the opening.

Other embodiments described herein provide a processing tool, comprising a vacuum chamber comprising a loading section and a processing section in an interior of the vacuum chamber, the processing section comprising a first support member having a plurality of openings to accept a modular charged particle device through each opening; a first electrical coupling adjacent to the first support member, the first electrical coupling having a plurality of connections in registration with each of the plurality of openings to connect with electrical conductors on the respective modular charged particle device upon insertion through the opening; a second support member disposed in juxtaposition with the first support member; and a second electrical coupling adjacent to the second support member, the second electrical coupling having control circuitry with an electrical connection in registration with each of the plurality of openings to connect with a control contact of the respective modular charged particle device upon insertion through the opening; and a substrate support disposed within the interior of the vacuum chamber and movable between the loading section and the processing section.

Other embodiments described herein provide a processing tool, comprising a vacuum chamber comprising a loading section and a processing section in an interior of the vacuum chamber, the processing section comprising a first support member having a plurality of openings to accept a modular charged particle device through each opening; a first electrical coupling adjacent to the first support member, the first electrical coupling having a plurality of connections in registration with each of the plurality of openings to connect with electrical conductors on the respective modular charged particle device upon insertion through the opening; a second support member disposed in juxtaposition with the first support member; and a second electrical coupling adjacent to the second support member, the second electrical coupling having control circuitry with an electrical connection in registration with each of the plurality of openings to connect with a control contact of the respective modular charged particle device upon insertion through the opening; and a substrate support disposed within the interior of the vacuum chamber and movable between the loading section and the processing section; a substrate placement chamber coupled to the vacuum chamber; and a thermal treatment station to thermally prepare a substrate for processing.

Other embodiments described herein provide a processing tool, comprising a substrate placement chamber; a processing chamber coupled to the substrate placement chamber, the processing chamber comprising a plurality of modular charged particle devices; and a thermal treatment station to thermally prepare a substrate for processing by the modular charged particle devices.

Other embodiments described herein provide a processing tool, comprising a vacuum chamber having a processing section, a loading section, and a substrate support movable between the processing section and the loading section, the processing section comprising a support structure for a plurality of modular charged particle devices, and the loading section comprising an optical inspection system.

Other embodiments described herein provide a method of processing a substrate, the method comprising heating the substrate to a processing temperature; and while maintaining the substrate at the processing temperature, processing the substrate using a plurality of charged particle devices concurrently in a processing chamber.

### BRIEF DESCRIPTION OF THE DRAWINGS

Some example embodiments are illustrated, by way of example and not limitation, in the accompanying figures. In the figures, like reference numbers indicate like features, and features might not be drawn to scale.

FIG. 1 is a schematic cross-sectional view of a processing tool according to one embodiment.

FIG. 2 is a detail view of a kinematic mount used in embodiments of the processing tool of FIG. 1, according to one embodiment.

FIG. 3 is an isometric view of a substrate support used in embodiments of the processing tool of FIG. 1, according to one embodiment.

FIG. 4 is an isometric view of a substrate support used in embodiments of the processing tool of FIG. 1, according to another embodiment.

FIG. 5 is a schematic plan view of a substrate support used in embodiments of the processing tool of FIG. 1, according to another embodiment.

FIGS. 6A-6D are plan views of processing system embodiments that can use the processing tool of FIG. 1.

### DETAILED DESCRIPTION

Systems and methods for charged particle processing of substrates are described herein. The systems generally use a vacuum chamber that has a loading section and a processing section, with a substrate support that can move a substrate between the loading section and the processing section. The processing section is configured to use a plurality of modular miniature charged particle devices to generate charged particles independently for application to the substrate.

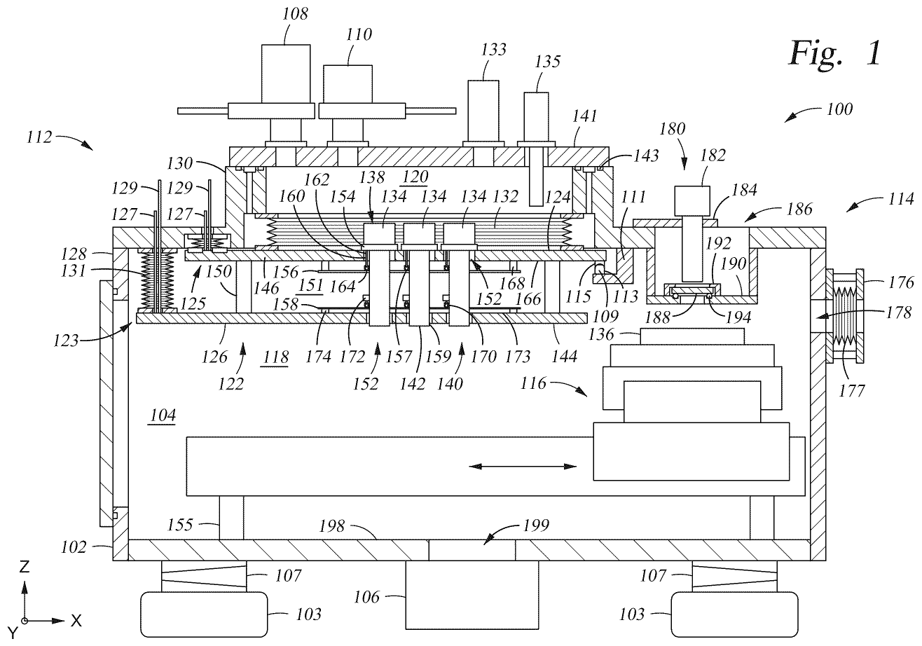

FIG. 1 is a schematic cross-sectional view of a processing tool 100 according to one embodiment. The processing tool 100 has an enclosure 102 that encloses an interior 104. A plurality of pumps, including a first pump 106, a second pump 108, and a third pump 110, operate to reduce a pressure within the enclosure to less than 10⁻⁷ Torr while processing a substrate. The processing tool 100 is thus a vacuum tool.

The enclosure 102 is elongated in one dimension, here denoted as the “x” dimension or direction. The elongated enclosure 102 has a processing section 112 and a loading section 114, which are displaced, on in the x-direction by a distance of at least about 2 dimensions of a substrate to be processed using the processing tool 100. A movable substrate support 116 is capable of moving between the loading section 114 and the processing section 112 to enable substrates to be loaded onto the substrate support 116, and unloaded from the substrate support 116, in the loading section, and to be processed in the processing section 112.

The interior volume 104 of the enclosure 102 is divided into two volumes, a first volume 118, which contains the substrate support 116, and a second volume 120. The first volume 118 extends the length of the enclosure 102 from the processing section 112 to the loading section 114. The second volume 120 is located at the processing section 112 only. The first volume 118 is separated from the second volume 120 by a separation assembly 122 that provides a floor 124 of the second volume 120 and part of a ceiling 126 of the first volume 118. The separation assembly 122 is attached to the enclosure 102 at a wall 128 thereof to provide a barrier to fluid communication between the first volume 118 and the second volume 120. In this case, the separation assembly 122 is attached to the enclosure 102 at a second volume wall 130 that surrounds the second volume 120 using a flexible wall member 132, which may be a bellows. The second volume wall 130 is a part of the wall 128 that defines the enclosure 102. The first pump 106 is fluidly coupled to the first volume 118. The second pump 108 and the third pump 110 are both fluidly coupled to the second volume 120. The separation assembly 122 allows the first volume 118 to be operated at a first volume pressure that is different from a second volume pressure of the second volume 120. For example, the first volume pressure can be greater than, or less than, the second volume pressure. In one case, in operation, the second volume pressure is less than the first volume pressure. For example, the first volume pressure can be 10⁻⁷ Torr or more while the second volume pressure is 10⁻⁹ Torr or less. In such cases, the first volume 118 can be said to operate under high vacuum while the second volume 120 operates under ultra high vacuum. In other cases, the first volume pressure can be less than the second volume pressure. For example, the second volume pressure can be near atmospheric pressure while the first volume pressure is vacuum such as 100 Torr.

The separation assembly 122 provides support for a plurality of charged particle devices 134 that emit charged particles into the first volume 118 for processing a substrate disposed on a stage 136 of the substrate support 116, when the substrate support 116 is positioned in the processing section 112. The charged particle devices 134 are disposed through the separation assembly 122, with an emitter portion 138 of each charged particle device 134 located in the second volume 120 and a direction portion 140 of each charged particle device 134 located in the first volume 118. Here, an exit end 142 of the charged particle devices 134 is exposed within the first volume 118 so that charged particles emitted within the emitter portion 138 and directed using the direction portion 140 exit the exit end 142 of the charged particle devices 134 into the first volume 118 and travel toward the stage 136 to interact with a substrate thereon. Here, the charged particle devices 134 are configured to emit charged particles from the exit end 142 in a beam configuration, and focus elements of the direction portion 140 of each charged particle device 134 are operable to configure the charged particles in a beam that may be focused, defocused, or collimated to any suitable extent depending on processing needs of the substrates to be processed. The charged particle devices 134 are thus elongated, at least in the direction portions 140, to provide propagation length usable to configure the charged particles into a beam configuration. Here, the separation assembly 122 is oriented in a substantially horizontal orientation, and the charged particle devices 134 are oriented to extend in a substantially vertical direction, which may be substantially perpendicular to a plane defined by the separation assembly 122.

The separation assembly 122 has a planar configuration here, but in other cases the separation assembly 122 can be curved and/or angled to any extent necessary depending on geometry of the enclosure 102 and/or the processing tool 100 generally. For example, the separation assembly 122 can have curved portions, angled portions, flat portions, or a combination thereof. The separation assembly 122 of FIG. 1 has a first support member 144 and a second support member 146. The first and second support members 144 and 146 are oriented in parallel, one to the other, and are spaced apart a selected distance. As noted above, in this case the processing tool 100, and the separation assembly 122, are oriented horizontally, such that the second volume 120 is located vertically above the first volume 118, but the tool 100 can generally take any suitable orientation.

A spacer 150 separates the first and second support members 144 and 146. The spacer 150 has a dimension in a direction perpendicular to the x-direction, here called the z-direction, that is selected to maintain the spacing between the first and second support members 144 and 146 at the selected spacing. The spacing is selected to afford easy electrical connection of each of the charged particle devices 134 to circuitry mounted adjacent to each of the first and second support members 144 and 146 when the charged particle devices 134 are inserted through the members 144 and 146. The spacer 150 is generally an object that has an extent in the x-direction and in a direction perpendicular to the x-direction and the z-direction, here called the y-direction, to provide uniform spacing between the first and second support members 144 and 146, and a dimension in the z-direction that is constant across the entire x-direction and y-direction extent of the spacer 150. The spacer 150 can be articulated in any suitable shape in the x-direction and the y-direction. For example, the spacer 150 can have a shape, extending in the x-direction and the y-direction, that is rectangular, square, circular, elliptical, oval, or even irregular in shape. Thus, the spacer 150 can be an open rectangular or square box, or a regular or irregular cylindrical object, such as an open curve-bound box. The spacer 150 can also be a plurality of partially cylindrical objects, a plurality of portions of a polygonal or curve-bounded box, or a plurality of posts, or a combination thereof. Here, the spacer 150 is shown as an object that has the aspect of a vertical wall that is parallel on two opposite sides. Alternately, the spacer 150 could have non-parallel portions, so long as the spacer 150 maintains a constant dimension in the z-direction for the entire x-direction and y-direction extent of the spacer 150. The spacer 150 can take any suitable shape in the x-direction and y-direction constrained only by geometrical aspects of different embodiments of the tool 100. The first and second support members 144 and 146, and the spacer 150, define, and may substantially enclose, an interior space 151 of the separation assembly 122.

Each of the first and second support members 144 and 146 has a plurality of openings 152 to accommodate the charged particle devices 134. The members 144 and 146 are configured such that the openings 152 of each member are in registration with the openings of the other plate. Thus, each opening 152 of the first support member 144 has a corresponding opening in the second support member 146, and the respectively corresponding openings 152 are aligned such that a charged particle device 134 can pass through corresponding openings in the first and second support members 144 and 146. As explained above, the spacing of the first and second support members 144 and 146 is selected such that each charged particle device 134 can make electrical connection with contacts adjacent to an opening 152 of the first support member 144 and with contacts adjacent to a corresponding opening 152 of the second support member 146 when the charged particle device 134 is inserted through the openings 152 and seated into place.

Each charged particle device 134 has a mounting member 154 that provides a mounting surface to attach the charged particle device 134 to the separation assembly 122. The mounting member 154 may be a plate for each of these charged particle devices 134, and upon installation into the tool 100, the mounting member 154 of each charged particle device 134 abuts the second support member 146 adjacent to the opening 152 through which the charged particle device 134 is inserted. The charged particle device 134 can thus be mounted to the separation assembly 122 for support during substrate processing operation. In other embodiments, the mounting member 154 could be a ring or plurality of tabs oriented and connected with the emitter portion 138 and the direction portion 140 in any suitable way. The mounting member 154 is generally secured to the second support member 146 using bolts, screws, or other suitable fasteners.

The processing tool 100 has a first electrical coupling 156 and a second electrical coupling 158, both disposed within the interior space 151 of the separation assembly 122. The first electrical coupling 156, disposed adjacent to the second support member 146, delivers power to all the charged particle devices 134, and the second electrical coupling 158, disposed adjacent to the first support member 144, transmits electrical signals to, and receives electrical signals from, from all the charged particle devices 134. The first electrical coupling 156 and the second electrical coupling 158 may be members of the separation assembly 122, as shown here.

The first electrical coupling 156 has circuitry, which may be digital circuitry, analog circuitry, or a combination thereof, to deliver power, which may be high voltage, low voltage, or intermediate voltage power, or any combination thereof, to power components of each charged particle device 134, such as the particle emitter housed within the emitter portion 138 and analog control elements of the direction portion 140. Thus, the first electrical coupling 156 may be, or may include, a power circuit member. The second support member 146 has a plurality of connection openings 160 that provide a pathway for electrical conductors 162 to extend from the emitter portion 138 through the second support member 146, when each charged particle device 134 is installed in the tool 100. The electrical conductors 162 of a charged particle device 134 are routed through the mounting member 154 into the emitter portion 138 thereof to power the emitter within the emitter portion 138. Electrical conductors (not shown) within the emitter portion 138 are also connected through the mounting member 154 to components of the direction portion 140 to power those components.

The first electrical coupling 156, which may be a circuit board, a plurality of circuit boards, or other suitable circuit structure, has a plurality of connections 164 that engage with the electrical conductors 162 of each charged particle device 134 and make electrical connection to place the electrical conductors 162, and thus the entire charged particle device 134, in electrical communication with the circuitry of the first electrical coupling 156 to receive power. The first electrical coupling 156 is located a selected distance from the second support member 146, adjacent to a facing surface 166 of the second support member 146 that faces the first support member 144, by one or more mounts 168 having dimension in the z-direction selected to dispose the electrical conductors 162 of each charged particle device 134 in electrical communication with the connections 164 when the mounting member 154 thereof abuts the second support member 146 along the surface that provides the floor 124 of the second volume 120, opposite from the facing surface 166. The mounts 168 connect the power circuit member to the second support member 146 physically. The first electrical coupling 156 has a plurality openings 157 through which the charged particle devices 134 extend to reach the openings 152 of the first support member 144. The openings 157 are in registration with the openings 152 of the first and second support members 144 and 146 when the first electrical coupling 156 is attached to the second support member 146.

The second electrical coupling 158 has digital circuitry for sending and receiving signals to each charged particle device 134. Thus, the second electrical coupling 158 may be, or may include, a signal circuit member. The second electrical coupling 158, which may be a circuit board, a plurality of circuit boards, or other suitable circuit structure, has electrical connections 170 that connect with control contacts 172 on the charge particle devices 134 for sending control signals between the charged particle devices 134 and the second electrical coupling 158. The second electrical coupling 158 thus handles all control of the charged particle devices 134.

As mentioned above, the direction portion 140 of each charged particle device 134 can have analog controls to control propagation of charged particles through the direction portion 140 and out of the charged particle device 134 through the exit 142 thereof. Each charged particle device 134 can include a D-A converter to convert digital control signals to analog control signals and apply the analog control signals to the analog controls of the direction portion 140. Thus, in some cases, the control circuitry of the second electrical coupling 158 is, or includes, digital circuitry, and the electrical connections and control contacts are digital components because they convey digital signals. In other cases, the second electrical coupling 158 can include one or more D-A converters to convert digital signals from digital control circuitry of the second electrical coupling 158 to analog signals. In such cases, the electrical connections and control contacts are analog components because they convey analog signals. In still other embodiments, control of the charged particles propagating through the direction portion 140 may be entirely analog, with analog control components of the second electrical coupling 158 providing analog signals to analog electrical connections and control contacts, to analog controls in the direction portion 140. Thus, in some cases, the circuitry of the second electrical coupling 158 can be, or can contain, analog components. In general, the second electrical coupling can generate or transmit digital control signals or analog control signals to control the analog control devices of the charged particle devices. Where digital signals are involved, the digital signals can be converted to analog signals using a D-A converter that may be a part of the charged particle device or a part of the second electrical coupling.

The charged particle devices 134 typically also include sensors (not shown). The sensors generate analog signals representing a condition of the charged particle device or an environment thereof. The signals are passed to the second electrical coupling 158 for use in controlling the charged particle devices 134 and the processes performed by the processing tool 100. These signals can be transmitted as analog signals to analog circuitry of the second electrical coupling 158, or the signals can be converted to digital signals using an A-D converter, which may be a part of the charged particle device 134 or the second electrical coupling 158. It should be noted that, whereas the processing tool 100 contains multiple modular charged particle devices, D-A and A-D conversion can be implemented differently for the different charged particle devices. That is, one or more of the charged particle devices 134 can have a D-A converter and one or more of the charged particle devices can have an A-D converter. The second electrical coupling 158 can have one D-A converter to handle transmissions between the second electrical coupling 158 and all the charged particle devices 134. The second electrical coupling 158 can have one A-D converter to handle transmissions between the second electrical coupling 158 and all the charged particle devices 134. The second electrical coupling 158 can have a plurality of D-A converters to handle transmissions between the second electrical coupling 158 and all the charged particle devices 134, where each D-A converter is electrically connected to one charged particle device 134 or where at least one D-A converter is electrically connected to more than one charged particle device 134. The second electrical coupling 158 can have a plurality of A-D converters to handle transmissions between the second electrical coupling 158 and all the charged particle devices 134, where each A-D converter is electrically connected to one charged particle device 134 or where at least one A-D converter is electrically connected to more than one charged particle device 134.

The electrical connections 170 of the second electrical coupling 158, and the control contacts 172 of the charged particle devices 134, may be digital components or analog components, as described above. In each case, the electrical connections 170 and the control contacts 172 may also transmit power, such as low-voltage power. In some cases, one or more of the electrical connections 170 and the control contacts 172 can include a combination of digital and analog transmission features, which may also include power transmission features. As mentioned above, the second electrical coupling 158 can have more than one of the electrical connections 170, which might not have the same configuration. To wit, some of the electrical connections 170 can be digital components, some of the electrical connections 170 can be analog components, and some of the electrical connections 170 can have a combination of digital and analog signal transmission. Likewise, some of the control contacts 172 can be digital components, some of the control contacts 172 can be analog components, and some of the control contacts 172 can have a combination of digital and analog features.

The second electrical coupling 158 has a plurality of openings 159, similar to the openings 157 of the first electrical coupling 156, in registration with the openings 152 when the second electrical coupling 158 is attached to the first support member 144. The openings, 152, 157, and 159 thus provide unobstructed access for the charged particle devices 134 to extend through the entire separation apparatus 122 between the first and second volumes 118 and 120, such that the emitter portions 138 of the charged particle devices 134 are housed within the second volume 120 while the direction portions 140 of the charged particle devices 134 extend to and/or into the first volume 118. It should be noted that the exit 142 of the charged particle devices 134 may be within the first volume 118, as shown here, or may be recessed with the first support member 144 a short distance.

As with the first electrical coupling 156, the second electrical coupling 158 is located a selected distance from the first support member 144, adjacent to a facing surface 173 of the first support member 144 that faces the second support member 146, by one or more mounts 174 having dimension in the z-direction selected to dispose the control contacts 172 of each charged particle device 134 in electrical communication with the electrical connections 170 of the second electrical coupling 158 when the mounting member 154 thereof abuts the second support member 146 along the surface that provides the floor 124 of the second volume 120, opposite from the facing surface 166. The mounts 174 connect the power circuit member to the first support member 144 physically.

The direction portion 140 of each charged particle device 134 has a plurality of analog controls that can be manipulated to control shape, focus, and direction of charged particles emitted from the exit 142 of the device 134. In many cases, the analog controls are used to form the charged particles into a beam having a desired dimension or focus and landing on a substrate at a target location. The controls are manipulated to articulate the beam to different locations on the substrate to “write” a pattern on the substrate using the beam of charged particles. Use of multiple modular miniature charged particle devices, as in the processing tool 100, enables much faster processing of substrates by allowing concurrent processing of sections of the substrate by independently operated charged particle devices. Where digital control signals are involved, each charged particle device to be controlled using digital signals has a digital-analog converter that translates digital signals from the second electrical coupling 158 into analog signals that are applied to the analog controls. Such configurations allow processing methods where different sections of a substrate are concurrently processed using, for example, electron beams writing different patterns, potentially with different beam size, shape, intensity, and dose. One location of a substrate can even be treated to a first writing process using a first charged particle device, and the same location can then be treated to second writing process using a second charged particle device of the same processing tool. The two writing processes can treat the location using different doses, intensities, and/or illumination areas to achieve any desired treatment effect on the substrate.

The first support member 144 and the second support member 146, along with the spacer 150, define an inner space wherein the first electrical coupling 156 and the second electrical coupling 158 are disposed, and through which the direction portions 140 of the charged particle devices 134 extend, and within which the various electrical connectors and contacts of the charged particle devices 134 connect to power and control signals using the electrical couplings 156 and 158. The charge particle devices 134 are inserted through the openings 152, 157, and 159 until the mounting member 154 abuts the second support member 146, at which time the electrical connections 162 connect with the connections 164 of the first electrical coupling 156, and the control contacts 172 connect with the electrical connections 170 of the second electrical coupling 158, making the charged particle devices 134 operative. When a charged particle device 134 is to be removed for maintenance, calibration, replacement, or other purpose, the mounting member 154 of the charged particle device 134 is unfastened from the second support member 146, and the charged particle device 134 is withdrawn from the openings 152, 157, and 159, disconnecting the charged particle device 134 from power and signals. The modular charged particle device 134, thus removed, can be transported to a maintenance and/or test facility equipped with similar plug-and-play features for maintenance, calibration, or other use. In other embodiments, the communication connections between a charged particle device and the processing tool 100 can be made manually, or using a mechanism other than the method described above, so power connections and communication connections can be made and disconnected separately, at different times, when installing and removing the charged particle devices 134 from the processing tool 100.

Use of an electrical coupling member to couple power to each charged particle device, as shown in FIG. 1 and described herein, enables power delivery to each charged particle device independent of every other charged particle device. Power can be separately switched to individual circuits of the first electrical coupling 156 for delivery to specific charged particle devices. In some cases, each charged particle device can have a separate, dedicated power supply. Thus, for a processing tool like the processing tool 100 that uses 9 charged particle devices, 9 power supplies can be connected, one power supply to one charged particle device, to power each charged particle device independently. The same can be done for processing tools using any number of charged particle devices in the configuration described herein.

In operation, the charged particle devices 134 emit charged particles at the emitter portion 138 and direct the charged particles in the direction portion 140 into the first volume 118 toward the stage 136 of the substrate support 116, on which a substrate is disposed for processing. The first electrical coupling 156 and the second electrical coupling 158 provide independent power and control to each charged particle device 134 so that different portions of the substrate can be processed in different ways concurrently and independently. Such capability ensures that a substrate can be processed using charged particles at a high rate by independently and concurrently processing different portions of the substrate.

As noted above, the substrate support 116 is movable between the processing section 112 and the loading section 114. A substrate is disposed on the stage 136 of the substrate support 116 in the loading section 114, and then moved to the processing section 112 by the substrate support. The processing tool 100 includes a substrate port 176 coupled to an opening 178 of the enclosure 102 to allow loading and unloading of substrates. A substrate handler (not shown) is generally configured to transport a substrate through the substrate port 176 and the opening 178 and deposit the substrate onto the stage 136, and to retrieve a substrate from the stage 136 and withdraw the substrate through the opening 178 and the substrate port 176. The substrate port 176 may be any suitable port, such as a door, gate, or slit. Slit valves and gate valves typically used in semiconductor processing systems, for example having slide gates, swing gates, iris gates, and the like, suitable for sealing vacuum chambers can be used as the substrate port 176. The port 176 may include a resilient member 177, for example a bellows, to provide passive vibration isolation at the port 176. The stage 136 generally includes a chucking feature to hold the substrate on the stage 136. The chucking feature can be an electrostatic chuck or vacuum chuck, depending on processing conditions within the tool 100.

In some cases, isolation can be applied directly to the substrate support 116. The substrate support 116 can, optionally, be disposed on one or more internal isolators 155, which as shown here can rest on the floor 198 of the enclosure 102. The internal isolators 155 shown here are within the enclosure 102, and thus within the vacuum area of the processing tool 100, and may be active isolators, passive isolators, or a combination thereof.

The processing tool 100 may include an inspection assembly 180 located at the loading section 114 for ascertaining characteristics of a substrate disposed on the stage 136 at the loading section 114. The inspection assembly 180 may include an optical system 182 for interrogating the substrate using electromagnetic radiation, which may include photographing the substrate using visible light, or any suitable frequency or spectrum of electromagnetic radiation. In one case, the substrate can be photographed, and digital image data formed from the photograph. The digital image data can be analyzed using image processing software to identify features of the substrate such as alignment features. Orientation and precise position of the substrate on the stage 136 can be ascertained using such methods.

The optical system 182 is here supported by a support 184 that is attached to the wall 128 that supports the separation assembly 122 and supports the optical system 182 outside the enclosure 102 and in registration with the loading section 114. In this case, the optical system 182 extends into an inward recess 186 of the enclosure that holds a window 188, through which the optical system can direct radiation toward the substrate on the stage 136 and receive reflected radiation representing features on the substrate. The window 188 can be held against a floor 190 of the recess 186 by a capture structure 192 and sealed against the floor 190 by a seal member 194. Information ascertained by the optical system 182 can be provided to the second electrical coupling 158, or can be rendered into control signals that are provided to the second electrical coupling 158, which can then distribute control signals to the charge particle devices 134 to process the substrate based on the information, for example position and orientation information, ascertained by the optical system 182.

The substrate support 116 moves along an x-direction movement component 196, which may be a rail system, disposed in a lower portion of the interior 104 of the enclosure 102, in this case on a floor 198 of the enclosure 102. The floor 198 has an opening 199 to allow evacuation of gases by operation of the first pump 106, which is coupled to the floor 198 at the opening 199 in fluid communication with the first volume 118 of the interior 104 of the enclosure 102. The first pump 106 is a vacuum pump, for example a turbomolecular pump, that can maintain a high vacuum within the interior 104 of the enclosure 102 in the first volume 118 thereof. The second and third pumps 108 and 110 are coupled to respective openings 197 in the second volume wall 130, in this case on a top of the processing tool 100, in fluid communication with the second volume 120 of the interior 104 of the enclosure 102. The separation assembly 122 allows the first pump 106 to control pressure within the first volume 118 independently from pressure within the second volume 120. The second and third pumps 108 and 110 can control pressure within the second volume 120 independently from pressure in the first volume 118. Thus, by operation of the first, second, and third pumps 106, 108, and 110, pressure within the first volume 118 can be maintained at a different value from pressure within the second volume 120. Thus, the emitters of the charged particle devices 134 can be operated at an emission pressure within the second volume 120, maintained by the second and third pumps 108 and 110, while the substrate is processed at a processing pressure within the first volume 118, different from the emission pressure, by operation of the first pump 106.

The processing tool 100 may have vibration isolation. The precision provided by processing using charged particles has best results when the effects of vibrations on position of the substrate and the charged particle devices 134 is minimized. Thus, the processing tool 100 may be supported on one or more isolators 103. The isolators 103 may be passive or active isolators. Passive isolators, such as resilient members having mechanical properties selected to minimize specific components of vibration, can be used. Active isolators are generally driven at a frequency selected to minimize, in cooperation with the passive isolators, a spectrum of vibration within the processing tool 100. Two isolators 103 are shown here, and any suitable number of isolators 103, such as two, three, four, or five, can be used. The processing tool 100 can also have one or more levelers 107 for adjusting the tool 100 to level with gravity. The levelers 107 are shown here coupled between the isolators 103 and the enclosure 102, but any configuration of leveler can be used. Two levelers 107 are shown here, but any suitable number of levelers 107 can be used.

The separation assembly 122 is supported within the interior 104 of the processing tool 100 by a plurality of kinematic mounts 109. Each kinematic mount 109 is disposed on a support 111 that extends from an interior surface of the enclosure 102. In this case, the support 111 is within the first volume 118 of the interior 104 because the second volume 120 is above the first volume 118, so the separation assembly 122 rests on the kinematic mounts 109 by gravity. One kinematic mount 109 is shown in this cross-sectional view, but any suitable number of kinematic mounts 109 may be used. For example, three kinematic mounts 109 can be used. Each kinematic mount 109 has a first member 113 coupled to the support 111 and a second member 115 coupled to the second support member 146 of the separation assembly 122. Here, the kinematic mounts 109 are coupled to the second support member 146, to directly support the second support member 146, but any configuration of the kinematic mounts 109 with the separation assembly 122 can be used.

Each of the members 144 and 146 of the separation assembly 122 can have a thermal control system. Here, a first thermal control system 123 is coupled with the first support member 144 and a second thermal control system 125 is coupled with the second support member 146. Each of the first and second thermal control systems 123 and 125 has a fluid inlet conduit 127 to deliver a thermal fluid to the respective plate 144/146. The fluid conduit 127 attached to each respective support member 144/146 at a port (not shown) that is in fluid communication with conduits (not shown) within each support member to circulate the thermal fluid within each support member. Each of the first and second thermal control systems 123 and 125 also has a fluid outlet conduit 129 to retrieve and withdraw the thermal fluid from the respective support member 144/146. Thermal fluid can be circulated through each support member 144/146, from the fluid inlet conduit 127, through an internal fluid conduit (not shown), to the fluid outlet conduit 129, continuously or intermittently to control a temperature of each support member 144/146. The fluid inlet conduit 127, internal fluid conduit, and fluid outlet conduit 129 of the first support member 146 defines a first cooling circuit, and the fluid inlet conduit 127, internal fluid conduit, and fluid outlet conduit 129 of the second support member 148 defines a second cooling circuit. Controlling the temperature of each support member 144/146 can minimize thermal dimension effects in each support member 144/146 that can affect coupling of the support members 144/146, and the electrical couplings 156/158, with the charged particle devices 134. Such temperature control can minimize the potential for mistargeting the charged particle devices 134 and loss of electrical connection between the electrical coupling members and the charged particle devices 134.

Each of the first thermal control system 123 and the second thermal control system 125 is coupled to the respective first and second support members 144 and 146 through an opening in the enclosure 102. A seal structure 131 couples each support member 144/146 with the enclosure 102 at the respective openings therein through which each respective thermal control system 125/127 is coupled. The seal structure 131 surrounds the opening formed in the enclosure 102 and the port in the respective plate such that the interior volume 104 of the enclosure 102 is isolated from the external environment at the openings. The seal structures 131 are flexible to maintain seal as the first and second support members 144 and 146 are moved by the kinematic mounts 109 so the separation assembly 122 can be positioned and leveled while maintaining seal at the first and second thermal control systems 123 and 125. The seal structure 131 may be bellows or any suitable flexible seal structure.

The first and/or second thermal control systems 123 and 125 can also provide thermal control for the charged particle devices 134. In general, the mechanical interface of each charged particle device 134 with the first support member 146 can also contain, or be, a thermal interface to transfer thermal energy between the charged particle device and the first support member 146. For example, the mounting member 154 of each charged particle device 134 can be made of, or can contain a thermally conductive material, such as a metal material or carbon material (e.g. graphite or carbon fiber) to transfer or transmit thermal energy between the charged particle device 134 and the first support member 146. Alternately, or additionally, a thermally conductive member, not shown here due to the scale of FIG. 1, can be disposed between the mounting member 154 of each charged particle device 134 to facilitate thermal transfer. The mechanical interface, if any, between each charged particle device 134 and the second support member 148 (for example, where there is any mechanical contact between any component of the charged particle device 134 and the second support member 148) can also be, or contain, a thermal interface to provide a similar function. The charged particle devices 134 can contain thermal conduits to transfer thermal energy between any portion of the charged particle device 134 and a thermal interface with the first support member 146, the second support member 148, or both. In general, the thermal conduits of each charged particle device 134 can be attached to the charged particle device 134 such that installing the charged particle device 134 within the processing tool 100 places the charged particle device 134 into thermal communication with the first and/or second thermal control systems 123 and 125. The thermal control systems 123 and 125, thus placed into thermal communication with components of the charged particle devices 134, can provide thermal control for each charged particle device 134.

A pressure sensor 133 is coupled to the enclosure 102 at the second volume 120. Pressure sensors like the pressure sensor 133 can be coupled to the enclosure 102 at any suitable location, and any number of pressure sensors can be used. The pressure sensor 133 produces signals representing a pressure within the second volume 120, which can be used to control operation of the second and third pumps 108 and 110. The second and third pumps 108 and 110 can be pumps designed to operate at different pressure regimes in order to achieve ultra high vacuum in the second volume 120. For example, the second pump 108 may be a high vacuum pump, such as a turbomolecular pump, that can achieve vacuum pressure of 10⁻⁹ Torr and the third pump 110 may be an ultra high vacuum pump, such as an ion pump, that can achieve vacuum pressure of 10⁻¹⁰ Torr. The two pumps can be useful because using an ultra high vacuum pump to pump a volume down from atmospheric pressure to ultra high vacuum can be a slow process. Using a faster pump, such as a high vacuum pump, to achieve an intermediate vacuum pressure, and then using the ultra high vacuum pump to achieve ultra high vacuum pressure, can reduce the pumpdown time. The pressure sensor 133 can signal when a pressure within the second volume 120 is suitable for using the third pump 110 to achieve ultra high vacuum as well as controlling the pumps 108 and 110 to maintain a target pressure within the second volume 120.

A thermal source 135 may be coupled to the enclosure 102, at any suitable location thereof, to provide infrared radiation within the enclosure 102. Infrared radiation can speed pumpdown of the chamber interior to high or ultra high vacuum by accelerating evolution of any gases from interior surfaces of the processing tool 100. Here, the thermal source 135 is coupled to the enclosure 102, extending through the enclosure 102 to the interior 104, at the second volume 120 thereof.

The thermal source 135, the pressure sensor 133, and the second and third pumps 108 and 110 are all, in this case, coupled to a lid 141 that forms a part of the enclosure 102. The lid 141 is coupled to the enclosure 102, here to the second volume wall 130, by a differential seal 143.

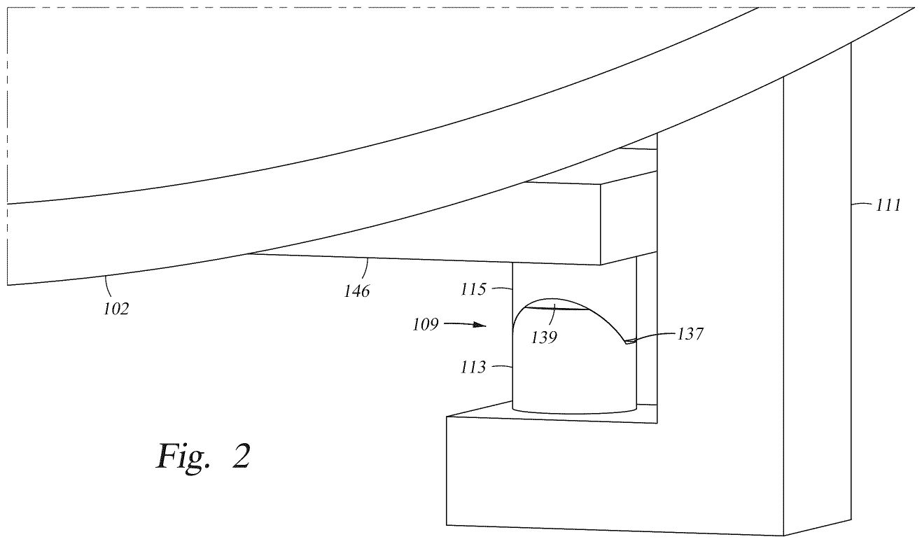

FIG. 2 is a detail view of one of the kinematic mounts 109 of the processing tool 100. The view in FIG. 2 is a perspective view that is rotated slightly from the view of FIG. 1 to show features of the kinematic mount 109 that are not visible in FIG. 1. As mentioned above, the kinematic mount 109 has a first member 113 and a second member 115. The first member 113 is coupled to the support 111, and the second member is coupled to the second support member 146, which is also sectioned here.

The first member 113 has a contoured first member contact surface 137. The second member 115 has a contoured second member contact surface 139. The first member contact surface 137 and the second member contact surface 139 are contoured to engage in contact to support the separation assembly 122 (FIG. 1). The contoured first member contact surface 137 has the shape of a flattened groove with a narrow bottom and wide top. The narrow bottom is flattened to provide a narrow floor of the groove. The sides of the groove (contact surface 137) slope upward linearly at an angle selected to provide support for the second support member 146 that constrains unwanted motion thereof. The contoured second member contact surface 139 has a shape that complements the shape of the contoured first member contact surface 137. In this case, the contoured second member contact surface 139 has the shape of a sloped, elongated, and flattened ridge. Each of the ridge of the contact surface 139 and the floor of the contact surface 137 are oriented in a radial direction of the separation assembly 122 and/or the second support member 146. In this case, although not shown, there are three kinematic mounts 109 supporting the second support member 146. The three kinematic mounts 109 are arranged with azimuthal spacing of 120 degrees, and the ridge and floor of the contact surfaces are all oriented toward a center of the separation apparatus 122 and/or the second support member 146. The flattened ridge of each contact surface 139 may contact the floor of each respective contact surface 137, or the sloped sides of each contact surface 139 may contact the sloped sides of each respective contact surface 137. The contact between the surfaces of the first and second members 113 and 115 of the three kinematic mounts 109 effectively constrain all lateral motion of the second support member 146 and the separation assembly 122 while providing vertical support for the separation assembly 122.

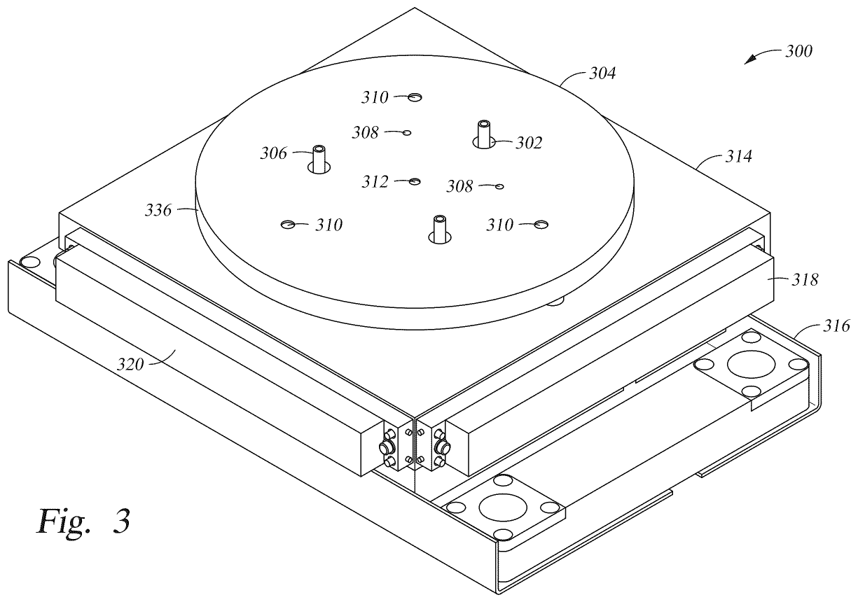

FIG. 3 is a perspective view of a substrate support 300 according to one embodiment. The substrate support 300 can be used in the processing tool 100 as the substrate support 116 in FIG. 1. The substrate support 300 has a stage 336, on which a substrate is disposed, and which has a plurality of lift openings 302 formed in a support surface 304 thereof. In this case there are three lift openings 302 but any suitable number of lift openings can be used, through which lift members 306 deploy to raise and lower the substrate for handling. The substrate support 300 generally has an interior volume (not shown) in which a lift mechanism can be disposed to operate to extend the lift member 306 through the lift openings 302 and to retract the lift members 306 into the stage 336, below the support surface 304.

In this case, the stage 336 incorporates an electrostatic chuck, with voltage members 308 and ground members 310. Other types of substrate supports or support stages can be used. For example, wafer clamp supports can also be used. The stage 336 may also include one or more temperature sensors (not shown), which may be located against an under side surface of the stage 336. The stage 336 may have an electrically conductive recess 312 in the support surface 304 at a central location. The electrically conductive recess 312 can be used to measure flow of electric current from one of the charged particle devices 134 (FIG. 1). The substrate support 300 is operated to position the stage 336 such that the electrically conductive recess 312 is in the path of charged particles travelling from one of the charged particle devices 134 (FIG. 1) to the stage 336. The electrically conductive recess 312 can be electrically connected to sensors to measure electrical properties of the recess 312, from which flow of charged particles into the recess 312 can be inferred.

The stage 336 is attached to a base 314. The base 314 is disposed on a movement member 316. The movement member 316 provides linear movement for the the stage 336 to position and move substrate for processing. A linear actuator (not shown) is coupled to the movement member 316. The linear actuator moves a component of the movement member 316 that is attached to the base 314. The processing system 100 may use an interferometry system for precision targeting of charged particles. Here, a first mirror 318 is attached to a first side of the base 314 and a second mirror 320 is attached to a second side of the base 314 orthogonal to the first side. The two mirrors can provide reflective measurement surfaces on the base 314 for measuring the location of the stage 336 to sub-micron precision. The substrate support 300 can include a rotational actuator (not shown) coupled to the base 314 to rotate the base 314 and the stage 336 as needed to orient the substrate disposed thereon. The rotational actuator can be located inside the substrate support 300. Coupling a rotational actuator to the base 314 can allow the interferometry system to measure rotational orientation of the stage 336 (and the base 314) using the mirrors 318 and 320 coupled to the base 314.

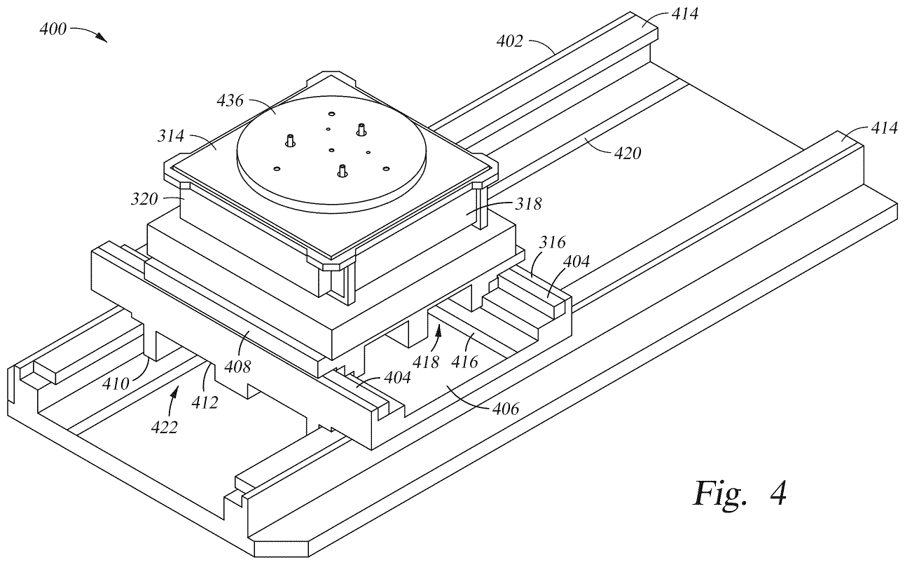

FIG. 4 is an isometric view of a substrate support 400 according to another embodiment. The substrate support 400 can be used in the processing tool 100 as the substrate support 116 of FIG. 1 The substrate support 400 has a stage 436, similar to the stage 336 of the substrate support 300 of FIG. 3. Whereas the first and second mirrors 318 and 320 of the substrate support 300 are attached using bolts, in this case brackets secure the first and second mirrors 318 and 320. The brackets securing the second mirror 320 are omitted from this view for illustration purposes.

Here, the movement member 316 is a first movement member, and is coupled to a second movement member 402. The first movement member 316 has two rails 404 along a first side 406 thereof, on which a carriage member 408 of the base 314 is movably disposed to ride linearly along the rails 404. The first movement member 316 has a coupling structure 410 on a second side 412 thereof, opposite from the first side 406, for coupling with the second movement member 402 to ride linearly along the second movement member 402. The second movement member 402 has two rails 414 that couple with the coupling structure 410 of the first movement member 316 to support linear motion of the first movement member 316. Thus, the first movement member 316 moves along the second movement member 402 in a first linear direction while the stage 436 moves along the first movement member 316 in a second linear direction perpendicular to the first linear direction.

The first movement member 316 may have a metric member 416 that can be used to measure position of the stage 436 with respect to the first movement member 316. The metric member 416, in this case, is attached to the first side 406 of the first movement member 316, on a surface facing the carriage member 408 of the base 314. The carriage member 408 of the base 314 has a recess 418 that faces the first side 406 of the first movement member 316. The metric member 416 extends along the first side 406 of the first movement member 316 facing the recess 418 of the carriage member 408. A sensor (not shown) can be attached to the carriage member 408 within the recess 418 to sense markings (not shown) on the metric member 416 for determining position and movement speed of the stage 436 with respect to the first movement member 316. The sensor and the metric member 416 thus constitute a linear encoder coupled between the stage 436 and the first movement member 316 for sensing position and movement speed of the stage 436. Note that this configuration of a linear encoder is only one example, and that a linear encoder can be incorporated into any suitable surfaces of the carriage member 408 and the first movement member 316.

The second movement member 402 also has a linear encoder. In a configuration similar to that of the first movement member 316, a metric member 420 is coupled to a side of the second movement member 402 that faces the coupling structure 410 of the first movement member 316 and extends into a recess 422 of the coupling structure 410. A sensor (not shown) can be attached to the coupling structure 410 facing the metric member 420 to sense position and velocity of the first movement member 316 with respect to the second movement member 402.

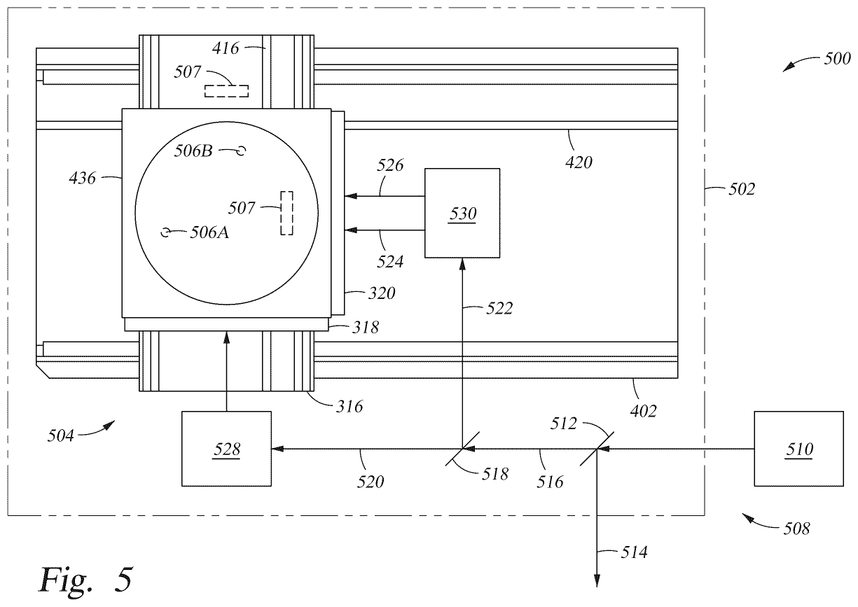

FIG. 5 is a schematic plan view of a substrate movement system 500 according to one embodiment. The substrate movement system 500 can be used with any embodiment of the processing tool 100 described herein. The substrate movement system is generally deployed within an enclosure 502, which can be the enclosure 102 of FIG. 1, to move and position substrates along the enclosure 502 from end to end. The substrate movement system 500 has a substrate support 504, which is generally similar to the substrate support 400 of FIG. 4, with the stage 436, the first movement member 316, and the second movement member 402. Sensors 506 for the linear encoders of the movement members are shown in phantom, since a first sensor 506A is coupled to an underside of the stage 436 to engage with the metric member 416 of the first movement member 316, and a second sensor 506B is coupled to an underside of the first movement member 316 to engage with the metric member 420 of the second movement member 402. Linear actuators 507 for moving the stage 436 with respect to the first movement member 316, and for moving the first movement member 316 with respect to the second movement member 402, are also shown in phantom as being located beneath structure of the substrate support 504.

The substrate movement system 500 has an interferometry system 508 for measuring position, and optionally orientation, of the stage 436. A beam source 510 provides a beam of light having sufficient coherence for precise interferometric measurements. The beam may be a laser beam. A first beam splitter 512 provides a reference beam 514 and a probe beam 516. A second beam splitter 518 splits the probe beam 516 into an x-beam 520 and a y-beam 522, which are used to measure the position of the stage 436 in two orthogonal dimensions. The x-beam 520 is directed to the first mirror 318 of the stage 436 by a first interferometer 528 and the y-beam 522 is directed to the second mirror 320 of the stage 436 (the first and second mirrors 316 and 318 are on opposite sides of the stage 436 in FIG. 5 versus FIG. 4) by a second interferometer 530. Reflected x- and y-beams are compared to the reference beam to compute distance by interferometry. The y-beam 522 may be further split into a first y-beam 524 and a second y-beam 526 that can be directed to the second mirror 320 at different locations to measure differential y-direction distance for ascertaining rotational orientation of the stage 436.

In operation, a substrate can be processed in the processing tool 100 using the substrate movement system 500. The linear encoders and the interferometry system 508 can be used to control application of charged particles from the charged particle devices 134 to precise locations on the substrate for precise durations. In one embodiment, the substrate support 504 is operated to scan the substrate at a constant velocity during processing. The sensors 506 of the linear encoders output signals representing position of the stage 436, and a controller uses the signals to control the linear actuators 507 to maintain a very constant scan speed of the substrate during processing. As the substrate is scanned, the analog controls of the charged particle devices 134 are operated, using control signals, which may be digital control signals, provided by the controller, to perform a writing operation on the substrate by directing a beam having controlled beam diameter, shape, intensity, and/or duration to target locations of the substrate. The interferometry system 508 continuously registers position of the stage 436 and detects any deviation from linear, constant velocity motion of the stage. The controller uses signals from the interferometry system to control the charged particle devices 134, by routing signals through the second electrical coupling 158 to the analog controls of the charged particle devices 134, modifying the writing process to compensate for deviation of stage movement from constant linear velocity.

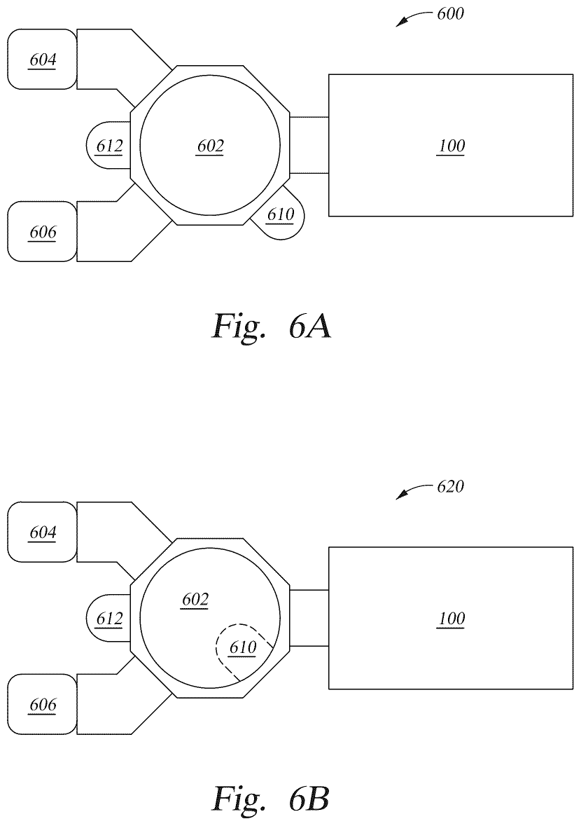

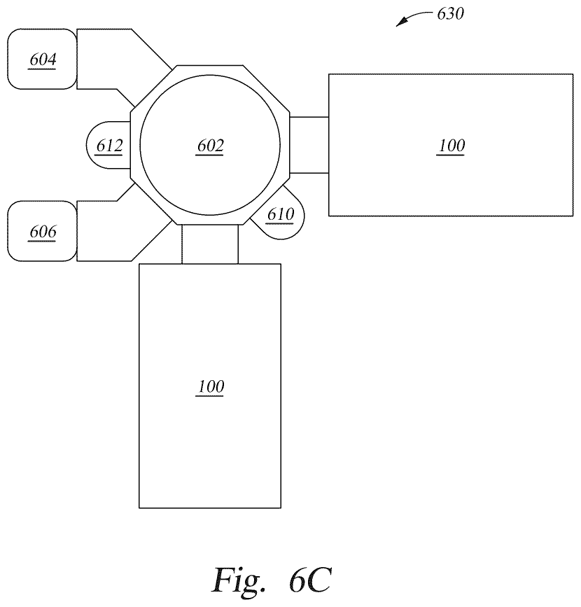

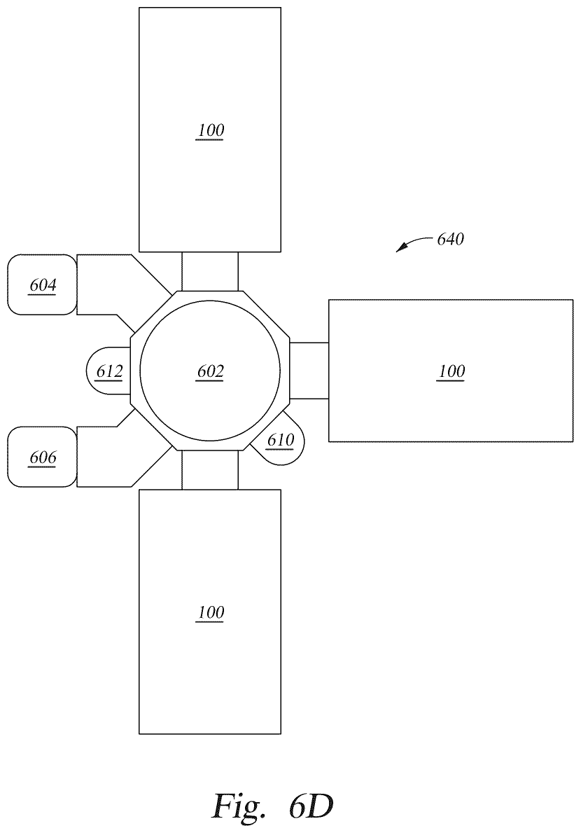

The processing tool 100 can be used in a processing system for mass production of processed substrates. FIGS. 6A-6D are schematic plan views of processing systems that use processing tools like the processing tool 100. FIG. 6A is a schematic plan view of a processing system 600 that uses one processing tool 100. The processing system 600 has a substrate placement chamber 602 for placing, retrieving, and moving substrates within the processing system 600. The substrate placement chamber 602 may have a substrate handler (not shown) for this purpose. A substrate input chamber 604 is coupled to the substrate placement chamber 602. A substrate output chamber 606 is also coupled to the substrate placement chamber 602. In some cases, a single substrate input-output chamber can be used instead of two separate chambers. The single substrate input-output chamber can have one substrate location or more than one substrate location. For example, the single substrate input-output chamber can have two substrate locations in a vertically movable substrate support that can be used for substrate input at a first elevation and substrate output at a second elevation.

A processing tool like the processing tool 100 is coupled to the substrate placement chamber 602. In this case, the substrate placement chamber 602 has eight coupling locations for coupling various tools and chambers to the substrate placement chamber 602. In the processing system 600, the substrate input and output chambers 604 and 606 are coupled to the substrate placement chamber 602 at locations substantially opposite from the processing tool 100, which is coupled to the substrate placement chamber 602 at a distal location. In other cases, the processing tool 100 can be coupled to the substrate placement chamber 602 at a location that is adjacent or proximate to the location of the substrate input chamber 604 or the substrate output chamber 606. In still other cases, the processing tool 100 can be coupled to the substrate placement chamber 602 at a location intermediate between the proximate locations and the distal location.

The processing system 600 has a thermal treatment station 610 for thermally preparing a substrate for processing in the processing tool 100. Because some applications of charged particle treatment can require extreme precision, thermal control of the substrate can be important to prevent thermal dimension changes that can be large with respect to processing precision requirements. The thermal treatment station 610 can be used to bring the substrate to, or near, thermal equilibrium at a processing temperature prior to loading the substrate into the processing tool 100. Equilibrating the substrate prior to loading into the processing tool 100 can prevent physical reaction of the substrate to sudden temperature change upon contacting the support surface of the stage.

In the processing system 600 of FIG. 6A, the thermal treatment station 610 is a chamber coupled externally to the substrate placement chamber 602. FIG. 6B is a schematic plan view of a processing system 620 according to another embodiment. The processing system 620 is identical in most respects to the processing system 600, except that in the processing system 620, the thermal treatment station 610 is located within the substrate placement chamber 602. In this case, the thermal treatment station 610 can be a chamber attached to an inner wall of the substrate placement chamber 602, or merely a heated surface that can accept, and thermally treat, a substrate. The thermal treatment stations described herein thus enable preheating a substrate to a processing temperature, prior to introducing the substrate to a processing tool or commencing processing, and then while maintaining the substrate at the processing temperature, processing the substrate using a plurality of charged particle devices concurrently in a processing chamber.

Each of the processing systems 600 and 620 have an optional buffer chamber 612 coupled to the substrate placement chamber 602. The buffer chamber 612 can be used to streamline logistics of substrate processing, or in some cases the buffer chamber 612 can, additionally or alternately, be used to orient a substrate for processing within the processing tool 100. Here, the buffer chamber 612 is coupled to the substrate placement chamber 602 at a location that is between the substrate input chamber 604 and the substrate output chamber 606, and directly opposite from the processing tool 100, but the buffer chamber 612 can be located at any suitable location.

FIGS. 6C and 6D are schematic plan views of processing systems 630 and 640 according to other embodiments. These processing systems are identical to the processing system 600 of FIG. 6A in most respects. The processing system 630 of FIG. 6C, however, has two processing tools 100 coupled to the substrate placement chamber 602, and the processing system 640 of FIG. 6D, has three processing tools 100 coupled to the substrate placement chamber 602.

Use of a processing system having a plurality of processing tools like the processing tool 100 provides exceptional processing flexibility. As noted above, one processing tool can process a single substrate using multiple charged particle devices with different control parameters, allowing for unparalleled speed and flexibility in processing substrates. Use of a processing system having two or three processing tools like the processing tool 100 multiplies the speed and flexibility available. In one case, for example, a substrate can be provided to a processing system having a first processing tool and a second processing tool, each processing tool configured to process a substrate using multiple, concurrently and independently operated and controlled, miniature modular charged particle devices. In the first processing tool, the substrate can be processed using settings to deliver charged particles in a beam having a first diameter and a first intensity. In the second processing tool, the substrate can be processed using setting to deliver charged particles in a beam having a second diameter and a second intensity, the second diameter different from the first diameter and the second intensity different from the first intensity. Such configurations allow for processing substrates in a first processing tool using a “coarse” processing method and in a second processing tool using a “fine” processing method.

While the foregoing is directed to embodiments of the present invention, other and further embodiments of the present disclosure may be devised without departing from the basic scope thereof, and the scope thereof is determined by the claims that follow.

We claim:

1. A processing tool, comprising:
a vacuum chamber;
a substrate support disposed in an interior of the vacuum chamber;
a first support member disposed in an interior of the vacuum chamber, the first support member having a plurality of openings to accept a modular charged particle device through each opening;
a first electrical coupling adjacent to the first support member, the first electrical coupling having a plurality of connections in registration with each of the plurality of openings to connect with electrical conductors on the respective modular charged particle device upon insertion through the opening;
a second support member disposed in the interior of the vacuum chamber in juxtaposition with the first support member; and
a second electrical coupling adjacent to the second support member, the second electrical coupling having control circuitry with an electrical connection in registration with each of the plurality of openings to connect with a control contact of the respective modular charged particle device upon insertion through the opening.

2. The processing tool of claim 1, further comprising a modular charged particle device disposed in each of the openings of the first support member, fastened to the first support member, and having electrical conductors electrically connected with contacts adjacent to the respective openings and a digital controller with a digital connector electrically connected with the digital communications contact of the respective openings.

3. The processing tool of claim 1, wherein the connections of the first electrical coupling and the second electrical coupling are passively connectable to the modular charged particle devices by physical insertion of the charged particle devices through the openings.

4. The processing tool of claim 2, further comprising a plurality of power couplings, each power coupling electrically connected to the contacts adjacent to one of the openings of the first support member.

5. The processing tool of claim 1, wherein the substrate support is an electrostatic chuck with an electrically conductive recess at a central location in the surface thereof.

6. The processing tool of claim 1, wherein the vacuum chamber further comprises a lid having a differential seal.

7. The processing tool of claim 1, further comprising an optical inspection system coupled to the vacuum chamber at the loading section thereof.

8. The processing tool of claim 1, wherein the first support member has a first cooling circuit disposed in an interior of the first support member and the second support member has a second cooling circuit disposed in an interior of the second support member.

9. The processing tool of claim 8, wherein the first cooling circuit, the second cooling circuit, or both are in thermal communication with the modular charged particle devices.

10. The processing tool of claim 1, further comprising a positioning system coupled to the substrate support in the interior of the vacuum chamber to move the substrate support between a loading section of the processing tool and a processing section of the processing tool.

11. The processing tool of claim 1, further comprising a spacer disposed between the first support member and the second support member, the spacer sized to ensure the power leads of a charged particle device inserted into each opening of the first support member connect with the respective plurality of contacts of the first electrical coupling and the digital connector of the charged particle device connects with the respective digital communication contact of the second electrical coupling.

12. The processing tool of claim 1, further comprising a plurality of power supplies to independently supply power to each modular charged particle device installed in the processing tool.

13. A processing tool, comprising:
a substrate placement chamber;
a processing chamber coupled to the substrate placement chamber, the processing chamber comprising a plurality of modular charged particle devices; and
a thermal treatment station to thermally prepare a substrate for processing by the modular charged particle devices.

14. The processing tool of claim 13, further comprising a flexible coupling that couples the processing chamber with the substrate placement chamber.

15. The processing tool of claim 13, wherein the thermal treatment station is a thermal processing chamber coupled to the substrate placement chamber.

16. The processing tool of claim 13, wherein the thermal treatment station is disposed in an interior of the substrate placement chamber.

17. The processing tool of claim 13, wherein the processing chamber is a first processing chamber, and further comprising a second processing chamber coupled to the substrate placement chamber, the second processing chamber comprising a plurality of modular charged particle devices.

18. A processing tool, comprising:
a vacuum chamber having a processing section, a loading section, and a substrate support movable between the processing section and the loading section, the processing section comprising a support structure for a plurality of modular charged particle devices, and the loading section comprising an optical inspection system.

19. The processing tool of claim 18, wherein the vacuum chamber has a lid that is coupled to a wall of the vacuum chamber by a differential seal.

20. The processing tool of claim 18, further comprising a positioning system coupled to the substrate support in the interior of the vacuum chamber.
